(19) United States
(12) Patent Application Publication
(10) Pub. No.: US 2011/0281393 A1
(43) Pub. Date: Nov. 17, 2011

(54) Method of Making an Organic Semiconductor Device

(76) Inventors: Mingqian He, Horseheads, NY (US); Michael Lesley Sorensen, Waverly, NY (US); Jianfeng Li, Ithaca, NY (US)

(21) Appl. No.: 12/781,291

(22) Filed: May 17, 2010

(51) Int. Cl. H01L 51/40

(52) U.S. Cl. 438/99; 257/E51.001

(57) ABSTRACT

A method of making an organic semiconductor device that comprises providing a surface comprising surface hydroxyl groups; applying an amine to the surface to form a first coated surface; applying a silane compound to the first coated surface to form a second coated surface; exposing the second coated surface to conditions sufficient to chemically react the silane compound with the hydroxyl groups to form a hydrophobic surface; and applying an organic semiconducting material to the hydrophobic surface.

### FIELD OF THE DISCLOSURE

The disclosure relates to a method of making an organic semiconductor device.

### BACKGROUND

The carrier mobility in an organic semiconductor device is linked to the device performance. The mobility is related to its structural quality and it is desirable to control molecular alignment of the organic semiconducting material. Conventional device fabrication includes applying organic semiconducting materials on a layer of silane which has been deposited via vapor deposition or solution-processing. These silane deposition methods can be expensive and time intensive.

### SUMMARY

The inventors have now developed a new method of making an organic semiconductor device wherein alignment of organic semiconducting material is facilitated by an amine catalyzed-silane treated surface; such a method can be done faster and cheaper than conventional techniques listed above.

One embodiment is a method comprising providing a surface comprising surface hydroxyl groups; applying an amine to the surface to form a first coated surface; applying a silane compound to the first coated surface to form a second coated surface; exposing the second coated surface to conditions sufficient to chemically react the silane compound with the hydroxyl groups to form a hydrophobic surface; and applying an organic semiconducting material to the hydrophobic surface.

Additional features and advantages will be set forth in the detailed description which follows, and in part will be readily apparent to those skilled in the art from the description or recognized by practicing the embodiments as described in the written description and claims hereof.

It is to be understood that both the foregoing general description and the following detailed description are merely exemplary, and are intended to provide an overview or framework to understand the nature and character of the claims.

### DETAILED DESCRIPTION

A first embodiment is a method comprising providing a surface comprising surface hydroxyl groups; applying an amine to the surface to form a first coated surface; applying a silane compound to the first coated surface to form a second coated surface; exposing the second coated surface to conditions sufficient to chemically react the silane compound with the hydroxyl groups to form a hydrophobic surface; and applying an organic semiconducting material to the hydrophobic surface.

The provided surface may be glass, silicon, or polymer. In one embodiment, the provided surface is glass. The provided surface may be present as a layer on a substrate, for example, the provided surface may be a glass layer on a silicon substrate. In another embodiment, the provided surface is a glass substrate. In yet another embodiment, the provided surface is a polymer, either alone or as a layer on a substrate.

The provided surface comprises surface hydroxyl groups. As used herein, the term hydroxyl group refers to the functional group (—OH). In some embodiments, the surface hydroxyl group may be present in the form of a silanol, where the hydroxyl group is bonded to a silicon atom. The number of surface hydroxyl groups on the provided surface may be increased, for example, by plasma cleaning the surface.

In one embodiment, the amine and the silane compound are applied in a two-step process. First, the amine is applied to the provided surface to form a first coated surface, followed by applying the silane compound to the first coated surface to form a second coated surface. The amine may be applied to the provided surface using any suitable technique, such as, dip coating or aerosol coating. In one embodiment, dip coating may comprise dipping the surface in an amine for a period of 10 seconds, 1 minute, 2 minutes or more. In one embodiment, the amine alone may be applied to the provided surface. In other embodiments, the amine may be dispersed in a solvent then applied to the provided surface.

The silane compound may be applied to the first coated surface using any suitable technique, such as, dip coating or aerosol coating. In one embodiment, dip coating may comprise dipping the surface in a silane compound for a period of 10 seconds, 1 minute, 2 minutes or more. In one embodiment, the silane compound alone may be applied to the first coated surface. In other embodiments, the silane compound may be dispersed in a solvent then applied to the first coated surface.

Appropriate solvents include those that are anhydrous, hydrophobic, slow to evaporate and non-reactive with the amine or silane compound. Example solvents include aliphatic hydrocarbons such as hexanes, cyclohexane, heptane; substituted aliphatic hydrocarbons such as ethyl lactate; and aromatic hydrocarbons such as toluene.

In one embodiment, the amine functions as a catalyst, promoting the reaction between the silane compound and the surface hydroxyl groups. In another embodiment, the amine functions as a crosslinker to form a network between the silicon of the silane, the nitrogen of the amine and the oxygen of the surface. In some embodiments, the amine may function as both a catalyst and a crosslinker.

In one embodiment, the amine comprises a primary, secondary, or tertiary amine, for example, an amine comprising one, two, or three R groups attached to the nitrogen atom. In one embodiment, the amine is a triethylamine. Another suitable amine is tetraethylenediamine.

The silane compound may be chosen to tailor the final properties of the treated surface. Suitable silanes include mono-, di, or tri-halogenated silanes and mono-, di-, or tri-alkylchlorosilanes. In one embodiment, the silane is trimethylchlorosilane. The solubility of the silane in the solvent can be considered when choosing the most appropriate combinations of silanes and solvents.

The reactions involving the silane with the amine and hydroxyl groups may occur spontaneously. In one embodiment, the reaction may be driven to completion via heating, for example, in an oven. The treated surface may be heated for example at 100 degrees C. for 10 minutes, 20 minutes, or more. Heating may also be employed to evaporate any excess solvent remaining on the surface.

Some embodiments include a drying step between and/or after amine and/or silane applications. Depending on the solvent, the first coated surface may be air dried for a period of time, such as 1 minute, 5 minutes, 10 minutes or more before the silane compound is applied. Furthermore, the second coated surface may be air dried for a period of time, such as 1 minute, 5 minutes, 10 minutes or more before heating.

In one embodiment, the hydrophobic surface formed between the silane and surface includes silicon of at least a portion of the silane bonded to at least a portion of oxygen of the surface hydroxyl groups. Hydrophobic surfaces include those surfaces that are antagonistic to water, mostly incapable of dissolving in water in an appreciable amount or being repelled from water or not being wetted by water. In one embodiment, the layer is a hydrophobic surface, for example, the surface has a water contact angle greater than 95 degrees.

In one embodiment, the organic semiconducting material is a polymer. In some embodiments, the polymer comprises a fused thiophene unit. Example fused thiophene units are disclosed in US Patent Application Publications 2007/0265418 and 2007/0161776, the contents of both being incorporated by reference herein.

One embodiment further comprises removing the amine or a reaction product of the amine from the second coated surface before applying the organic semiconducting material. For example, an amine salt may be formed during the reaction. The amine salt may be removed from the second coated surface via washing with an appropriate solvent.

The method described above may be used to prepare an organic semiconductor device. The term “organic semiconductor device” includes any structure comprising the surface, silane, and applied organic semiconducting material described above. The term “organic semiconductor device” also includes any other devices incorporating that structure, such as TFTs and OFETs.

Various embodiments will be further clarified by the following examples.

Top-contact bottom-gate transistors using P2TDC17FT4 of the formula:

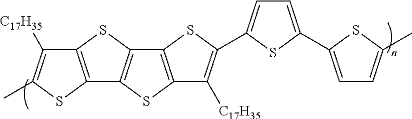

as the organic semi-conducting channel were fabricated in ambient conditions. Heavily doped Si<100> wafer substrates were used as gate electrodes with a 300 nm thermally grown silicon dioxide layer as the gate dielectric. The substrates were cleaned by sonication in semiconductor grade acetone and isopropanol for 10 minutes in each solvent, and then given a 15 minutes air plasma treatment. Prior to the two-step dipping process as the surface treatment, pre-cleaned Si/SiO₂ samples were baked at 200° C. for 15 minutes in N₂ for dehydration.

For this treatment, pre-cleaned substrates were firstly immersed in a 1.0 volume % solution of triethylamine in anhydrous toluene for 1 minute, and then followed by a quick dipping in a 0.01M solution of chlorosilane compounds in anhydrous toluene for another 1 minute. Excess silane was removed by the rinsing with ethanol and acetone, and drying under a stream of nitrogen. Substrates were subsequently baked in nitrogen at 100° C. for 30 minutes. The treated wafers showed a water contact angle greater than 90°.

Solutions of polymers in pentachloroethane (3 mg/ml) were prepared by heating to 170° C. for 30 minutes with stirring to speed up dissolution. Polymer films were then deposited by spin-coating at 1500 RPM for 40 seconds. The films were baked at 150° C. in a vacuum chamber to remove the solvent prior to thermal evaporation of top contacts. Gold contacts (50 nm) for source and drain electrodes were vacuum-deposited at a rate of 2.5 Å/s through a metal shadow mask that defined a series of transistor devices with a channel length (L) of 80 μm and a channel width (W) of 1 mm. Polymeric transistors were characterized in air.

Table 1 lists data for contact angle, TFT device mobility, on/off ratio and threshold voltage for 4 samples prepared as described above; an octylchlorosilane with and without the amine pretreatment and a trimethylchlorosilane with and without the amine pretreatment. The data reported in Table 1 illustrates the beneficial effect of the amine treated surfaces compared to those without the amine treatment.

TABLE 1

| | Dontact | TFT Device | | |
|---|---|---|---|---|
| | Angle | Mobility | | Vt |
| Method | (Degrees) | (cm²/V · s) | I on/off | (Volts) |
| Single dipping in | ~80 | 0.05-0.07 | 5 | −7 |
| Octylchlorosilane | | | | |
| Two-steps dipping in | ~90 | 0.07-0.085 | 5 | −3 |
| amine/Octylchlorosilane | | | | |
| Single dipping in | 80-85 | 0.05-0.08 | 6 | −2 |
| Trimethylchlorosilane | | | | |
| Two-steps dipping in | 95-100 | 0.075-0.13 | 6 | −1.5 |
| amine/ | | | | |
| Trimethylchlorosilane | | | | |

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made without departing from the spirit or scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A method comprising:
providing a surface comprising surface hydroxyl groups;
applying an amine to the surface to form a first coated surface;
applying a silane compound to the first coated surface to form a second coated surface;
exposing the second coated surface to conditions sufficient to chemically react the silane compound with the hydroxyl groups to form a hydrophobic surface; and
applying an organic semiconducting material to the hydrophobic surface.

2. A method of claim 1, wherein the provided surface is plasma cleaned.

3. A method of claim 1, wherein the amine is triethylamine.

4. A method of claim 1, wherein the silane is selected from a mono-, di, or tri-halogenated silane, and a mono-, di-, or tri-alkylchlorosilane.

5. A method of claim 1, wherein the silane is trimethylchlorosilane.

6. A method of claim 1, wherein the surface is glass.

7. A method of claim 1, wherein the surface is silicon.

8. A method of claim 1, wherein the surface is a polymer.

9. A method of claim 1, wherein the hydrophobic surface has a water contact angle greater than 95 degrees.

10. A method of claim 1, wherein the organic semiconducting material is a polymer.

11. A method of claim 10, wherein the polymer comprises a fused thiophene unit.

12. A method of claim 1, further comprising removing the amine or a reaction product of the amine from the second coated surface before applying the organic semiconducting material.
